(19) United States
(12) Patent Application Publication
(10) Pub. No.: US 2009/0289668 A1
(43) Pub. Date: Nov. 26, 2009

(54) Output driver circuit for an integrated circuit

(75) Inventors: Alberto Baldisserotto, Fuquay Varina, NC (US); Steven Broome, Apex, NC (US); Jason Thurston, Raleigh, NC (US); Carl Thomas Gray, Apex, NC (US)

Correspondence Address: NIXON & VANDERHYE P.C., 901 N. Glebe Road, 11th Floor, Arlington, VA, 22203-1808, US

(73) Assignee: ARM Limited, Cambridge (GB)

(21) Appl. No.: 12/153,792

(22) Filed: May 23, 2008

(51) Int. Cl. H03K 3/00

(52) U.S. Cl. 327/108

(57) ABSTRACT

An integrated circuit 2 is provided with an output driver circuit 12. The output driver circuit 12 one side provides between a first power supply 20 and a second power supply 18 a first transistor 16, a first output 22, a first resistor 14 and, connected in parallel with the first resistor 14, a first bypass transistor 24. The first bypass transistor 24 is controlled by a first bypass control voltage vbp such that as the first output voltage of the first output 22 approaches the second power supply voltage of the second power supply 18, the first bypass transistor 24 serves to bypass the first resistor 14 and provide a single-ended impedance of the output driver circuit 12 which approximates to zero. On the complementary side of the output driver circuit 12 there are similarly provided a second transistor 28, a second resistor 26 and a bypass transistor 32.

### BACKGROUND OF THE INVENTION

1. Field of the Invention

This invention relates to the field of integrated circuits. More particularly, this invention relates to output driver circuits within integrated circuits that are used to generate an output signal in the form of a voltage difference between a first output and a second output of the integrated circuit.

2. Description of the Prior Art

It is known to provide integrated circuits with output driver circuits for generating high data rate output signals. FIG. 5 of the accompanying drawings illustrates a standard current mode logic (CLM) driver circuit for driving an output signal across an output load R2 between a first output and a second output. A first input signal vin switches a first transistor MNN and a second complementary input signal switches a second transistor MNP. The action of the first input signal vin and the second input signal vip is to drive the first output high whilst the second output is driven low so as to represent a first data state and to drive the second output high and the first output low to represent a second data state.

It will be appreciated that as data rates increase it becomes increasingly difficult to maintain large output swings whilst maintaining an acceptable level of jitter. As the output swing diminishes in amplitude and the level of jitter increases, the transmit eye mask associated with the output driver circuit reduces in size thereby imposing additional constraints upon the receiver circuit and/or leading to an increase in the data error rate.

FIG. 6 of the accompanying drawings illustrates one known output driver circuit seeking to address these problems. This circuit uses an additional I/O power supply at a higher level (vddh) to which the output signal is driven. This approach uses a disadvantageously increased amount of power during operation. Furthermore, there is the a need to provide the higher level I/O supply voltage vddh.

FIG. 7 of the accompanying drawings illustrates a further known form of output driver circuit. This example uses a full rail CMOS level driver to increase the magnitude of the voltage swings. However, such output driver circuits are subject to higher levels of jitter that introduces a performance limitation.

The present invention seeks to provide an output driver circuit for use within an integrated circuit that yields an increased amplitude of voltage swing in the output signal without significantly increasing the level of jitter.

### SUMMARY OF THE INVENTION

Viewed from one aspect the present invention provides an integrated circuit having an output driver circuit coupled to a first output and a second output of said integrated circuit such that a voltage difference between said first output and said second output provides an output signal, said output driver circuit comprising:

a first transistor coupled between a first power supply and said first output, said first transistor being switched by a first input signal;

a first resistor coupled between said first output and a second power supply;

a second transistor coupled between said first power supply and said second output, said second transistor being switched by a second input signal;

a second resistor coupled between said second output and said second power supply;

a first bypass transistor coupled between said first output and said second power supply so as to be connected in parallel with said first resistor, said first bypass transistor being switched by a first bypass control signal; and

a second bypass transistor coupled between said second output and said second power supply so as to be connected in parallel with said second resistor, said second bypass transistor being switched by a second bypass control signal; wherein

said first bypass transistor is switched by said first bypass control signal to provide a low impedance path that bypasses said first resistor as a first output voltage at said first output approaches a second power supply voltage of said second power supply; and

said second bypass transistor is switched by said second bypass control signal to provide a low impedance path that bypasses said second resistor as a second output voltage at said second output approaches a second power supply voltage of said second power supply.

The output driver circuit of the present technique uses the first transistor in combination with the first resistor to provide switching in the first output signal with a relatively low level of jitter while the first bypass transistor controlled by the first bypass control signal serves to “short circuit” the first resistor as the first output voltage approaches the second power supply voltage thereby increasing the amplitude of the voltage swing in the output signal. A complementary arrangement is provided to drive the second output in a similar way and to retain the balanced form of the output driver circuit.

The first bypass control signal can be provided in a variety of different ways. In some embodiments the first input signal may serve as the first bypass control signal. This enables the first bypass transistor to be switched off when not needed but has the disadvantage of increasing the power consumed in the pre-drive stages since a larger capacitance will need to be driven to switch both the first transistor and the first bypass transistor.

An alternative approach is that the first bypass control signal can be held at a controlled constant voltage with the first bypass transistor switched on. This voltage can be provided by diode bypassing the first bypass control signal, by grounding the first bypass control signal, with an analog controller or in some other way.

In a similar way to the above the second bypass control signal for controlling the second bypass transistor can be provided.

It is convenient to provide embodiments in which the first transistor and the second transistor have opposite conduction types (i.e. P-type or N-type). The first bypass transistor can be of an opposite conductance type to the first transistor and the second bypass transistor can be of an opposite conduction type to the second transistor.

The first transistor and the second transistor may be coupled to the first power supply via a current limiting gate. The term coupled encompasses both direct and indirect connect.

The first power supply may be a ground rail and the second power supply may be a positive supply rail. This positive supply rail may also serve as the positive supply rail for the remainder of the integrated circuit or at least part thereof.

Viewed from another aspect the present provides an integrated circuit having an output driver means coupled to a first output and a second output of said integrated circuit such that a voltage difference between said first output and said second output provides an output signal, said output driver means comprising:

first transistor means for switching by a first input signal, said first transistor means being coupled between a first power supply and said first output;

first resistor means coupled between said first output and a second power supply;

second transistor means for switching by a second input signal, said second transistor means being coupled between said first power supply and said second output;

second resistor means coupled between said second output and said second power supply;

first bypass transistor means for switching by a first bypass control signal, said first bypass transistor means being coupled between said first output and said second power supply so as to be connected in parallel with said first resistor means; and

second bypass transistor means for switching by a second bypass control signal, said second bypass transistor means being coupled between said second output and said second power supply so as to be connected in parallel with said second resistor means; wherein

said first bypass transistor means is switched by said first bypass control signal to provide a low impedance path that bypasses said first resistor means as a first output voltage at said first output approaches a second power supply voltage of said second power supply; and

said second bypass transistor means is switched by said second bypass control signal to provide a low impedance path that bypasses said second resistor means as a second output voltage at said second output approaches a second power supply voltage of said second power supply..

Viewed from a further aspect the present invention provides a method of operating an integrated circuit having an output driver circuit coupled to a first output and a second output of said integrated circuit such that a voltage difference between said first output and said second output provides an output signal, said method comprising the steps of:

switching a first transistor coupled between a first power supply and said first output using a first input signal;

providing a first resistor coupled between said first output and a second power supply;

switching a second transistor coupled between said first power supply and said second output using a second input signal;

providing a second resistor coupled between said second output and said second power supply

switching a first bypass transistor coupled between said first output and said second power supply so as to be connected in parallel with said first resistor using a first bypass control signal; and

switching a second bypass transistor coupled between said second output and said second power supply so as to be connected in parallel with said second resistor using a second bypass control signal; wherein

said first bypass transistor is switched by said first bypass control signal to provide a low impedance path that bypasses said first resistor as a first output voltage at said first output approaches a second power supply voltage of said second power supply; and

said second bypass transistor is switched by said second bypass control signal to provide a low impedance path that bypasses said second resistor as a second output voltage at said second output approaches a second power supply voltage of said second power supply.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates an integrated circuit including an output driver circuit;

FIG. 2 schematically illustrates an output driver circuit;

FIGS. 3 and 4 schematically illustrate the operation of the output driver circuit of FIG. 2 in generating opposite output voltage swings;

FIG. 5 illustrates a CML driver circuit;

FIG. 6 schematically illustrates an output driver circuit including a high level supply voltage; and

FIG. 7 schematically illustrates an output driver circuit serving as a voltage mode driver.

### DESCRIPTION OF THE PREFERRED EMBODIMENTS

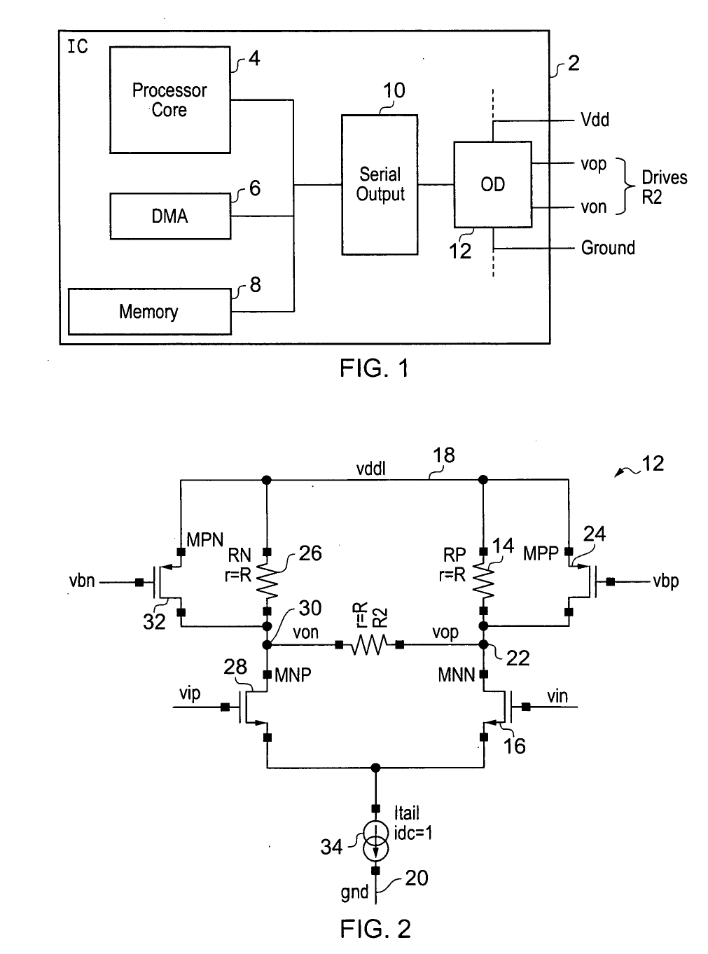

FIG. 1 schematically illustrates an integrated circuit 2 including a plurality of on-chip components such as a processor core 4, a DMA unit 6, a memory 8, a serial output circuit 10 and an output driver circuit 12. It will be appreciated that the integrated circuit 2 could include many different circuit elements and/or additional circuit elements to those illustrated.

The present technique is principally concerned with the form of the output driver circuit 12 illustrated in FIG. 1. It will be appreciated that multiple such output driver circuits 12 could be provided within a single integrated circuit 2.

The output driver circuit 12 includes a first output driven to a first output voltage vop and a second output driven to a second output voltage von. The first output and the second output connect to an output load R (such as a signal line and receiver circuit). The output driver circuit 12 is supplied with a first power supply which is a ground voltage and a second power supply which is a positive rail voltage Vdd. The ground and positive rail voltage may also provide power to the other circuit elements 4, 6, 8, 10 within the integrated circuit 2.

In operation the output driver circuit 12 serves to output a data value of one state by driving the first output signal vop toward the positive rail voltage Vdd and the second output signal von toward the ground voltage. The opposite data state is provided by the output driver circuit 12 by driving the second output signal von toward the positive rail voltage Vdd and the first output signal vop toward the ground voltage. It will be understood by those skilled in this technical field that important performance characteristics of the output driver circuit 12 are the amplitude (magnitude) of the voltage swing it is able to produce between the first output and the second output at a given data rate together with the amount of data jitter associated with the output signal being generated.

FIG. 2 illustrates the output driver circuit 12 in more detail. At one side of the output driver circuit there are disposed between the first power supply 20 and the second power supply 18, a current limiting gate 34 (power supply tail), a first transistor 16, a first output 22, a first resistor 14 and, connected in parallel with the first resistor 14, a first bypass transistor 24. The first transistor 16 is switched by a first input signal vin applied to its gate. The first bypass transistor 24 is switched by a first bypass control signal vpp supplied to its gate.

The other side of the output driver circuit 12 provides between the first power supply 20 and the second power supply 18 the current limiting gate 34, a second transistor 28, a second output 30, a second resistor 26 and, connected in parallel with the second resistor 26, a second bypass transistor 32. The second transistor 28 is switched by a second input signal vip applied to its gate. The second bypass transistor 32 is switched by a second bypass control signal vpn applied to its gate.

The output driver circuit 12 operates by switching on and off in anti-phase with one another the first transistor 16 and the second transistor 28 so as to respectively provide different data values to be output between the first output 22 and the second output 30 through the generation of an appropriate voltage swing across an external load R2.

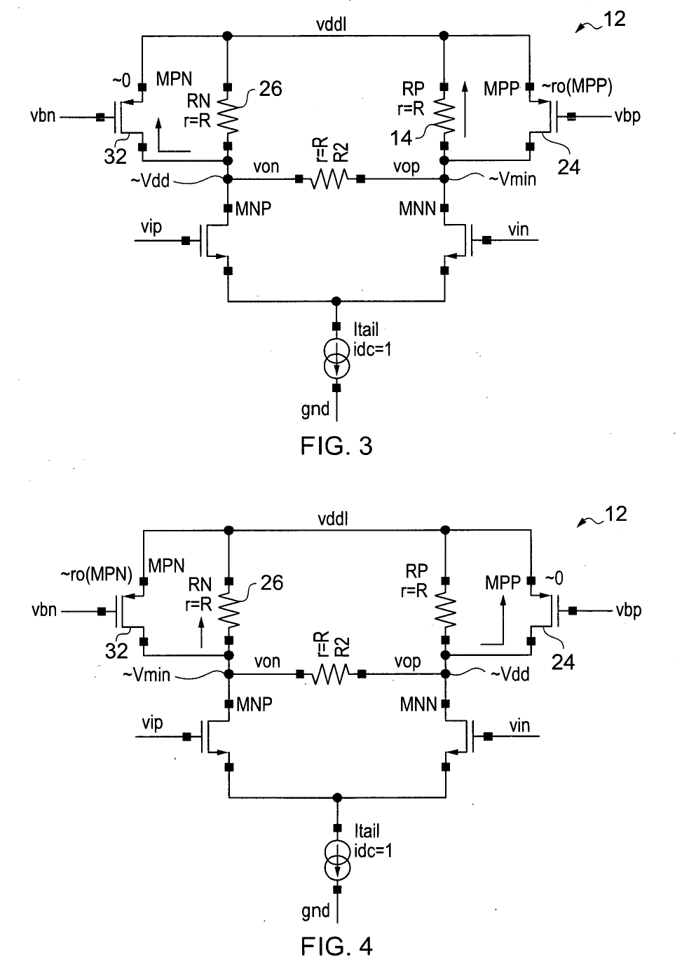

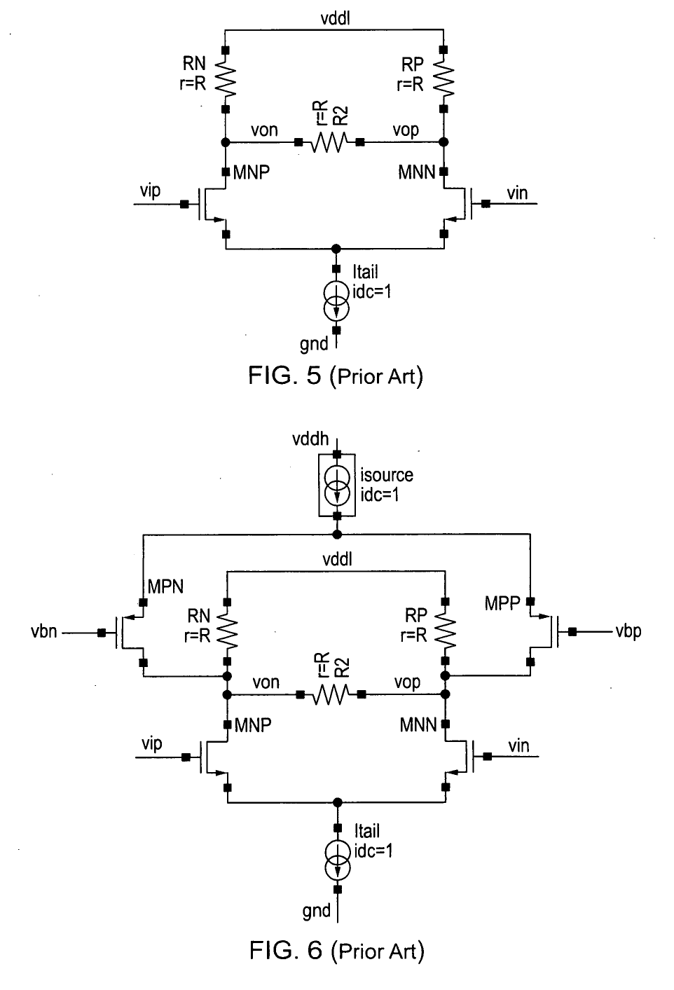

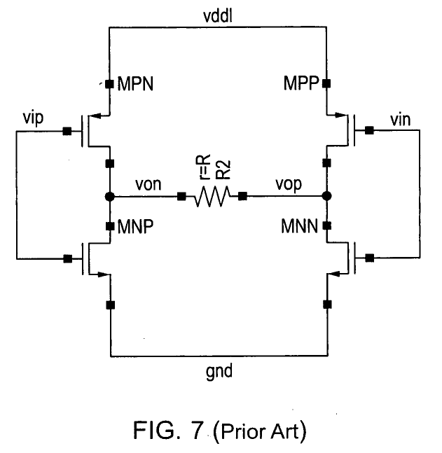

FIGS. 3 and 4 illustrate the operation of the output driver circuit 12. The output driver circuit has input signals vip/vin and output signals vop/von across the external load R2. While the first output voltage vop at the first output 22 is low, the first bypass transistor 24 operates in its active region and the single-ended impedance of the output driver circuit 12 will be given by the parallel combination of RP (the resistance of the first resistor 14), the resistance through the first bypass transistor (ro(MPP)) and the resistance through the first transistor (ro(MNN)). This parallel combination of resistances will yield a total resistance of approximately RP. The single-ended impedance when the first output 22 is low is dominated by the resistance of the first resistor 14.

As the first output voltage vop at the first output 22 rises and starts to approach the second power supply voltage vddl of the second power supply 18, then the resistance through the first bypass transistor 24 decreases and eventually effectively short circuits the first resistor 14. This results in the single-ended output impedance varying from RP to zero during this part of the cycle. FIG. 3 shows the situation where the first output voltage vop is low and the single-ended impedance is dominated by the first resistor 14.

FIG. 4 shows the situation in which the first output voltage vop is high and approaching the second power supply voltage. In this state the resistance of the first bypass transistor 24 is low and effectively short circuits (bypasses) the first resistor 14 to give a single-ended output impedance that is close to zero.

The above has described the single-ended operation on the “p” side of the output driver circuit 12. The complementary behaviour also occurs on the “n” side. On the “n” side the second bypass transistor 32 serves to bypass the second transistor 24 as the second output voltage von approaches the second power supply voltage vddl.

The effect of the provision of the first bypass transistor 24 controlled by the first bypass control signal vbp and the second bypass transistor 32 controlled by the second bypass control signal vbn is to increase the output voltage swing (vout=vop-von) from R2*I*RN/(R2+RP+RN) to R2*I*RN/(R2+RN). A result of this is that the efficiency of the output driver is improved and the common mode voltages raised thereby allowing for a larger output amplitude swings.

It will be appreciated that the present technique serves to dynamically change the output impedance in order to increase the output voltage swing without requiring the need of an additional higher voltage I/O power supply vddh.

There are a variety of ways to provide the first bypass control signal vbp and the second bypass control signals vbn which serve to switch the first bypass transistors 24 and the second bypass transistor 32. One approach is to diode bias these voltages through a current mirror or by grounding them. The bypass control voltages vbp and vbn could be provided in the form of a controlled voltage provided in a variety of different ways, such as an analog voltage controller. Using a fixed controlled voltage in this way does not impose an additional power burden upon the pre-drive stages of the integrated circuit 2, but results in the first bypass transistor 24 and the second bypass transistor 32 being switched on at all times. An alternative approach is to drive the first bypass control signal vbp with the first input signal vin and the second bypass control signal vbn with the second input signal vip. This increases the power required in the pre-drive stages since the first bypass transistor 24 and the second bypass transistor 32 will be relatively large physical devices with significant capacitance. However, the first bypass transistor 24 and the second bypass transistor 32 controlled in this way will be switched off when they are not needed thereby allowing the output driver circuit 12 to more closely match the output load at the transition point of the data.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

We claim:

1. An integrated circuit having an output driver circuit coupled to a first output and a second output of said integrated circuit such that a voltage difference between said first output and said second output provides an output signal, said output driver circuit comprising:
a first transistor coupled between a first power supply and said first output, said first transistor being switched by a first input signal;
a first resistor coupled between said first output and a second power supply;
a second transistor coupled between said first power supply and said second output, said second transistor being switched by a second input signal;
a second resistor coupled between said second output and said second power supply;
a first bypass transistor coupled between said first output and said second power supply so as to be connected in parallel with said first resistor, said first bypass transistor being switched by a first bypass control signal; and
a second bypass transistor coupled between said second output and said second power supply so as to be connected in parallel with said second resistor, said second bypass transistor being switched by a second bypass control signal; wherein
said first bypass transistor is switched by said first bypass control signal to provide a low impedance path that bypasses said first resistor as a first output voltage at said first output approaches a second power supply voltage of said second power supply; and
said second bypass transistor is switched by said second bypass control signal to provide a low impedance path that bypasses said second resistor as a second output voltage at said second output approaches a second power supply voltage of said second power supply.

2. An integrated circuit as claimed in claim 1, wherein said first input signal also serves as said first bypass control signal.

3. An integrated circuit as claimed in claim 1, wherein said first bypass control signal is held at a substantially constant control voltage such that said first bypass transistor is held in a high conductance state.

4. An integrated circuit as claimed in claim 3, wherein said substantially constant control voltage is provided by one of:
(i) a controlled voltage; and
(ii) diode biasing said first bypass control signal.

5. An integrated circuit as claimed in claim 1, wherein said first transistor and said second transistor have opposite conductance types.

6. An integrated circuit as claimed in claim 1, wherein said first transistor and said second transistor are coupled to said first power supply via a current limiting gate.

7. An integrated circuit as claimed in claim 1, wherein said first power supply is a ground rail.

8. An integrated circuit as claimed in claim 1, wherein said second power supply is a positive supply rail.

9. An integrated circuit as claimed in claim 1, wherein said second input signal also serves as said second bypass control signal.

10. An integrated circuit as claimed in claim 1, wherein said second bypass control signal is held at a substantially constant control voltage such that said second bypass transistor is held in a high conductance state.

11. An integrated circuit as claimed in claim 10, wherein said substantially constant control voltage is provided by one of:
(i) a controlled voltage; and
(ii) diode biasing said second bypass control signal.

12. An integrated circuit having an output driver means coupled to a first output and a second output of said integrated circuit such that a voltage difference between said first output and said second output provides an output signal, said output driver means comprising:
first transistor means for switching by a first input signal, said first transistor means being coupled between a first power supply and said first output;
first resistor means coupled between said first output and a second power supply;
second transistor means for switching by a second input signal, said second transistor means being coupled between said first power supply and said second output;
second resistor means coupled between said second output and said second power supply;
first bypass transistor means for switching by a first bypass control signal, said first bypass transistor means being coupled between said first output and said second power supply so as to be connected in parallel with said first resistor means; and
second bypass transistor means for switching by a second bypass control signal, said second bypass transistor means being coupled between said second output and said second power supply so as to be connected in parallel with said second resistor means; wherein
said first bypass transistor means is switched by said first bypass control signal to provide a low impedance path that bypasses said first resistor means as a first output voltage at said first output approaches a second power supply voltage of said second power supply; and
said second bypass transistor means is switched by said second bypass control signal to provide a low impedance path that bypasses said second resistor means as a second output voltage at said second output approaches a second power supply voltage of said second power supply.

13. A method of operating an integrated circuit having an output driver circuit coupled to a first output and a second output of said integrated circuit such that a voltage difference between said first output and said second output provides an output signal, said method comprising the steps of:
switching a first transistor coupled between a first power supply and said first output using a first input signal;
providing a first resistor coupled between said first output and a second power supply;
switching a second transistor coupled between said first power supply and said second output using a second input signal;
providing a second resistor coupled between said second output and said second power supply
switching a first bypass transistor coupled between said first output and said second power supply so as to be connected in parallel with said first resistor using a first bypass control signal; and
switching a second bypass transistor coupled between said second output and said second power supply so as to be connected in parallel with said second resistor using a second bypass control signal; wherein
said first bypass transistor is switched by said first bypass control signal to provide a low impedance path that bypasses said first resistor as a first output voltage at said first output approaches a second power supply voltage of said second power supply; and
said second bypass transistor is switched by said second bypass control signal to provide a low impedance path that bypasses said second resistor as a second output voltage at said second output approaches a second power supply voltage of said second power supply.
